(19) United States
(12) Patent Application Publication
(10) Pub. No.: US 2013/0069488 A1
(43) Pub. Date: Mar. 21, 2013

(54) PIEZOELECTRIC PRESSURE SENSITIVE TRANSDUCER APPARATUS AND METHOD

(71) Applicants: John H. GOODEMOTE, Sauquoit, NY (US); Ryan J. CUMMISKEY, Clay, NY (US); Dennis C. STIMSON, Baldwinsville, NY (US); David A. RUGGLES, San Antonio, TX (US)

(72) Inventors: John H. GOODEMOTE, Sauquoit, NY (US); Ryan J. CUMMISKEY, Clay, NY (US); Dennis C. STIMSON, Baldwinsville, NY (US); David A. RUGGLES, San Antonio, TX (US)

(73) Assignee: LOCKHEED MARTIN CORPORATION, Bethesda, MD (US)

(21) Appl. No.: 13/538,752

(22) Filed: Jun. 29, 2012

Related U.S. Application Data
(60) Provisional application No. 61/503,843, filed on Jul. 1, 2011.

(51) Int. Cl. H01L 41/113; H04R 31/00; H01L 41/053

(52) U.S. Cl. CPC H01L 41/1132; H01L 41/053; H04R 31/006
USPC 310/348; 29/25.35

(57) ABSTRACT

A sensor includes a first plate, a second plate, and a piezoelectric material portions. The piezoelectric material portions are positioned between the first plate and the second plate. The area of the piezoelectric material portions is less than the area of the plates. The plates can be supported with a center support structure. The width of the sensor is significantly greater than its height. The interstitial space is filled with a flexible material. An outside wall isolates the inside from the outside

### RELATED APPLICATIONS

This application claims the benefit under 35 U.S.C. § 119(e) of prior U.S. Provisional Patent Application No. 61/503,843, filed Jul. 1, 2011, which is incorporated herein by reference.

### TECHNICAL FIELD

Various embodiments described herein relate to a system and a method for forming a pressure sensor (hydrophone), which can be used as part of an array that includes a number of pressure sensors. The sensors and the array are used for receiving acoustic sound in the water. In one embodiment, the sensors are used on vessels, such as a submarine, as part of a Sonar system.

### BACKGROUND

Sonar is a well known apparatus having both civilian and military applications. Sonar (originally an acronym for SOund Navigation And Ranging) is a technique that uses sound propagation, usually underwater, to navigate, communicate with or detect other vessels. Sonar uses sensors placed in arrays to receive sound. The arrays can be deployed in many ways. Some sonar arrays are towed behind a ship or submarine. Towing an array of sensors or hydrophones presents many problems. Another way to deploy an array is by mounting sensors to the hull of a ship, such as a submarine. Hull mounted sonar arrays are generally built up from separate components at several hull mount sites on a hull. Typically, there are a number of hull mount sites that are aligned along the starboard side of the hull and an equal number of hull mount sites aligned along the port side of the hull In many instances, the individual sensors are made from solid ceramic plates or solid ceramic blocks and so are also heavy. Heavy sensors results in a heavy array of sensors. The heavy arrays add to the weight of the assembly needed for a hull mounted array.

Sensor hydrophone converts acoustic signal into an electrical signal using a piezoelectric material. The piezoelectric material is bound by first plate and a second plate. Acoustic pressure waves impinge on the first plate and the second plate or top and bottom surfaces of the sensor, respectively. The variation in pressure squeezes or strains the active piezoelectric material to generate a voltage which is substantially proportional to a voltage produced by the piezoelectric material, such as ceramic. The chemical properties of the piezoelectric material generate the voltage. The voltage potential resulting from the acoustic sound waves is measured an input to signal processing systems to produce useful information in locating other ships and other structures. Sonar can be used to locate ships above or below the surface and can also be used to determine characteristics of the ocean floor. For example, one use of the sensors or hydrophones can be for undersea exploration for oil or other natural resources.

### BRIEF DESCRIPTION OF THE DRAWINGS

FIG. 1 is a side view of a vessel including an array of sonar sensors, according to an example embodiment.

FIG. 2 is a perspective of a portion of the array in which a baffle, SCP, and VIM are one molded piece, according to an example embodiment.

FIG. 3 is a schematic cross sectional view of an individual acoustic pressure sensor, according to an example embodiment.

FIG. 4 is a side section view of an acoustic pressure sensor, according to an example embodiment.

FIG. 5 is a top view of an acoustic pressure sensor, according to an example embodiment.

FIG. 6 is a blown up perspective view of an acoustic pressure sensor, according to an example embodiment.

FIG. 7 is a perspective view of a finished acoustic pressure sensor, according to an example embodiment.

FIG. 8 is a blown up perspective view of another embodiment of an acoustic pressure sensor, according to an example embodiment.

FIG. 9 is a perspective view of a square acoustic pressure sensor partially assembled, according to an example embodiment.

FIG. 10 is a perspective view of a square acoustic pressure sensor as assembled, according to an example embodiment.

FIG. 11 is a perspective view of a round acoustic pressure sensor as assembled, according to an example embodiment.

FIG. 12 is a blown up perspective view of a round acoustic pressure sensor, according to an example embodiment.

FIG. 13 is a perspective view of the round acoustic pressure sensor encased in a viscioelastic material, according to an example embodiment.

FIG. 14 is a perspective view of a partially assembled round acoustic pressure sensor, according to an example embodiment.

FIG. 15 is a perspective view of a fully assembled round acoustic pressure sensor, according to an example embodiment.

FIG. 16 is one possible cross-section view along line A-A in FIG. 15, according to an example embodiment.

FIG. 17 is one possible cross-section view along line A-A in FIG. 15, according to an example embodiment.

### DETAILED DESCRIPTION

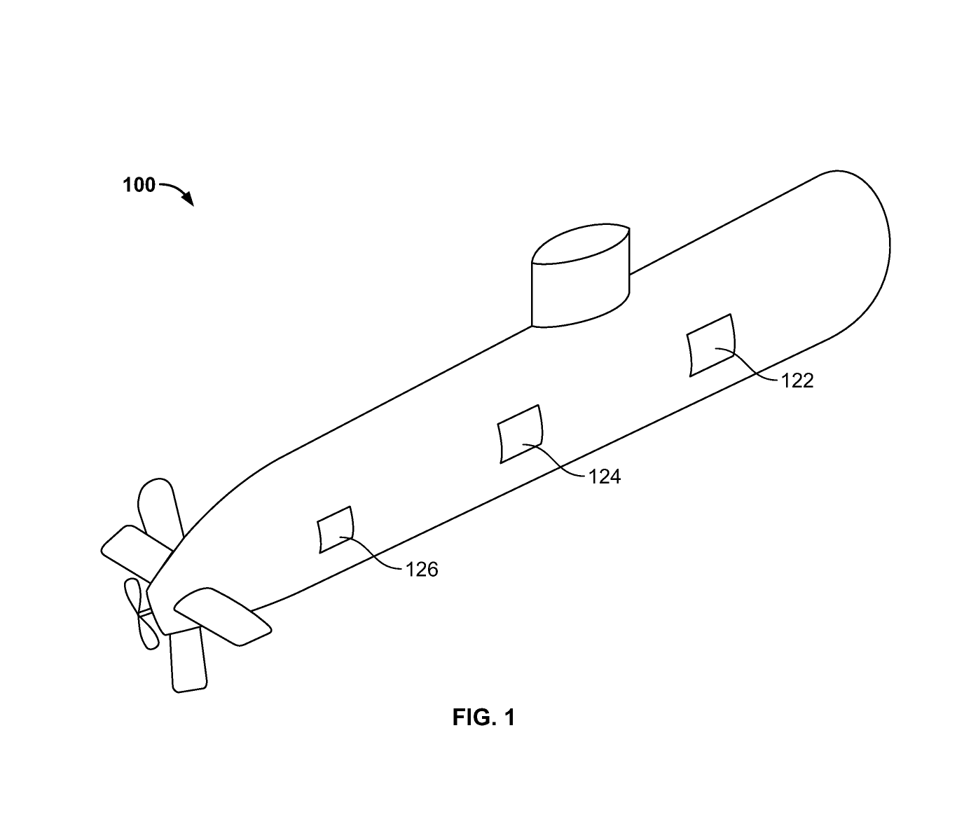

FIG. 1 is a side view of a vessel 100 including an array of sonar sensors 120, according to an example embodiment. The vessel 100 is a submarine. It should be understood that other types of vessels may also include an array of sonar sensors. The array of sonar sensors 120 includes a number of subarrays of sonar sensors that are added to other components to form a panel, such as panels 122, 124, 126. The vessel's 100 port side is shown with three panels 122, 124, 126 that include sonar sensors. The panels 122, 124, 126 are positioned along the port side of the vessel 100. The starboard side of the vessel 100 also includes three similarly positioned panels (not shown) of sonar sensors. In total, there are six panels on the vessel that form the array 120. It should be noted that other arrays can have a different number of panels. Some vessels 100 may include more panels and some vessels may include fewer panels to form an array of sensors.

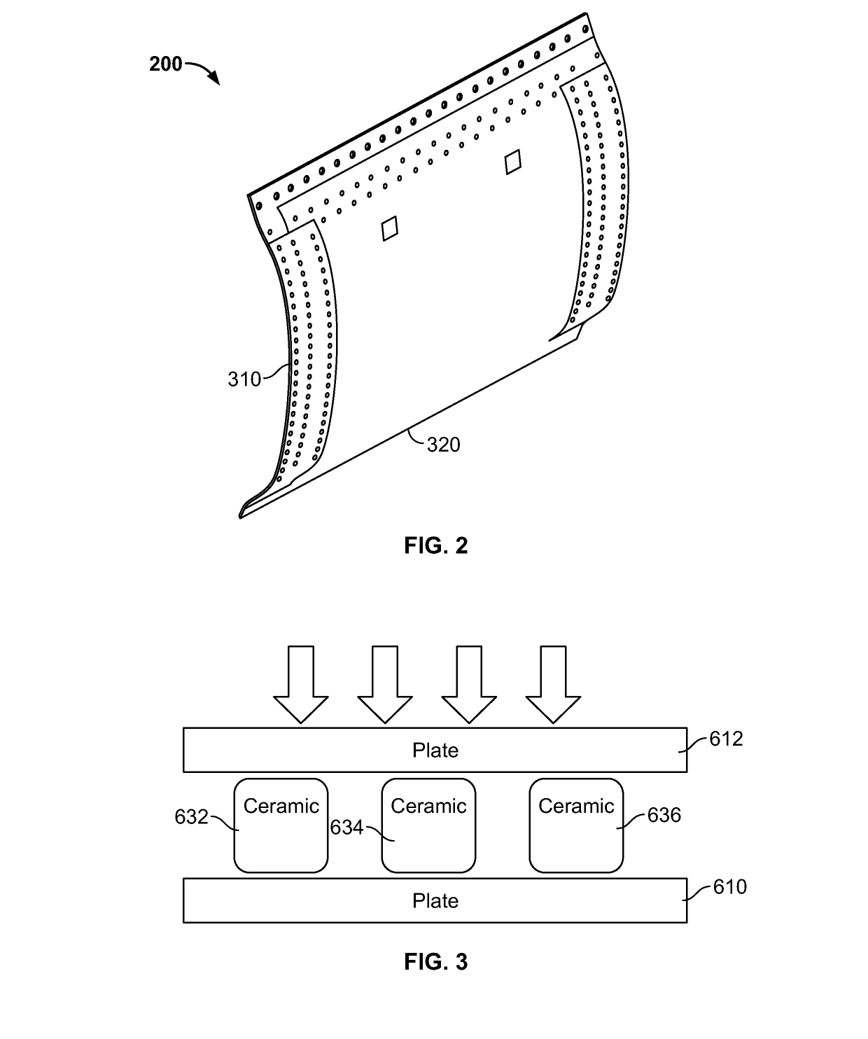

FIG. 2 is a perspective of a portion of one of the panels, such as panel 122, of the array of sonar sensors 120, according to an example embodiment. The sensors may be laid out in a hexagonal pattern to increase packing density which increases performance.

FIG. 3 is a schematic cross sectional view of an individual acoustic pressure sensor 600, according to an example embodiment. The sensor 600 includes a first plate 610 and a second plate 612. Sandwiched between the first plate 610 and the second plate 612 are columns of ceramic material, such as columns 632, 634, 636. The columns can be of any shape. For example, the cross section may be circular or square or rectangular in shape and these are low cost readily available parts. The columns of ceramic material are a piezoelectric material that produces electricity in response to pressure or force placed on the material. An electrical charge accumulates in certain solid materials (such as the ceramic used for the columns 632, 634, 636 in the pressure sensor 600) in response to applied mechanical strain. Sound waves, whether in water, air, or otherwise, are pressure waves. When the sound wave or pressure wave strikes a first plate 610 the force is transferred to the columns 632, 634, 636 of piezoelectric material.

In fact, the columns 632, 634, 636 act as pressure concentrators. Pressure is force per unit area. When the force passes through the columns 632, 634, 636, the force is distributed over a smaller area and therefore pressure at the columns 632, 634, 636 is higher than the pressure on the first plate 610. The columns 632, 634, 636 of piezoelectric material generate electricity when subjected to a pressure change. Electrical connections are made to the columns which produce signals in response to the variations of pressure caused by sound waves.

In other embodiments, the ceramic or piezoelectric material need not be formed in columns. The first plate 610 and the second plate 612 have major surfaces with an area. The ceramic or piezoelectric material interacts with less than the full surface area of these major surfaces. The ceramic or piezoelectric material could be shaped as cubes or even shorter flat rectangles.

The surface area of the ceramic or piezoelectric material interfacing with the major surface of one of the first plate 610 and the second plate 612 will be less than the surface area of the major surface. The piezoelectric material or ceramic material is heavy. In such an arrangement, less ceramic material is used and the resultant sensor formed is lighter than previous sensors. Previous sensors included a substantially solid plate of ceramic between a first plate and a second plate. Using portions of ceramic or piezoelectric material rather than a solid plate of ceramic between the first plate 610 and the second plate 612 lightens the sensor. The ratios between the surface area of the first plate 610 or the second plate 612 (caps) and the piezoelectric material portions is in a range of between 3:1 to 11:1. It has been found that surface area ratios within the above range provide at least as good if not superior performance in a sensor that is less costly to build and which has less weight.

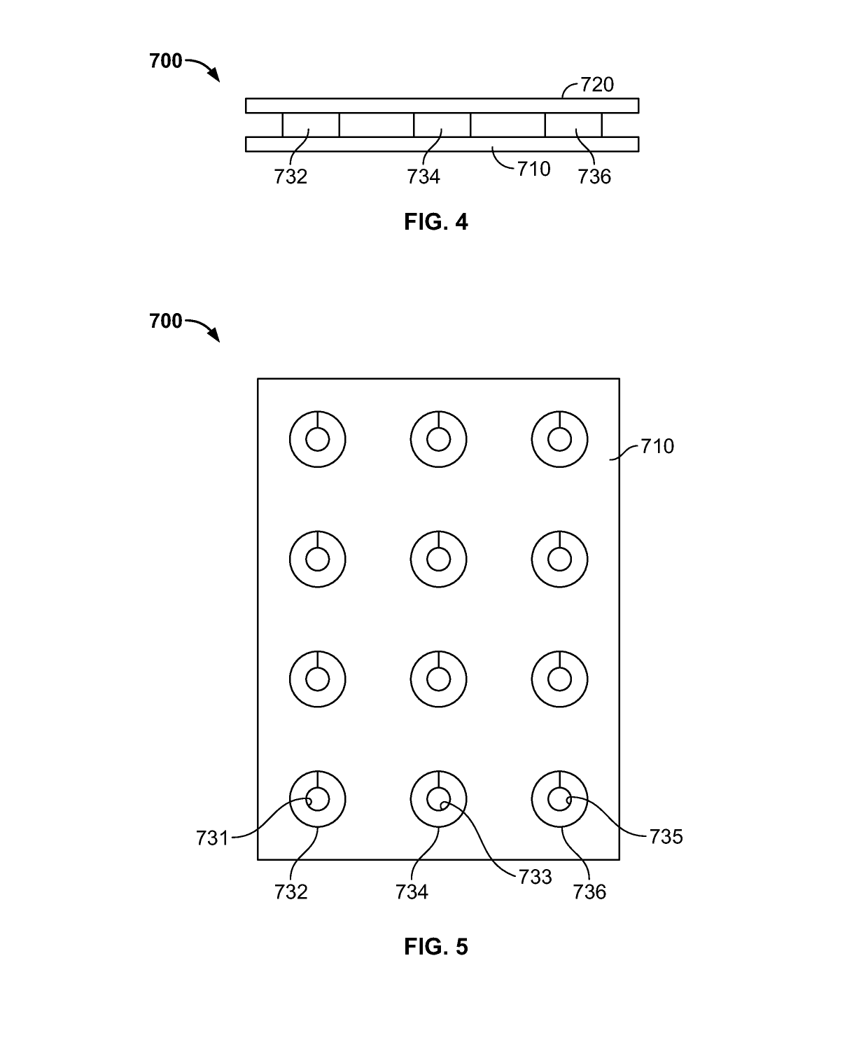

FIG. 4 is a side section view of an acoustic pressure sensor 700, according to an example embodiment. The pressure sensor 700 includes a first plate 710 and a second plate 720. Sandwiched between the first plate 710 and the second plate 720 are columns of piezoelectric material, three of which can be seen, 732, 734, 736. FIG. 5 is a top view of an acoustic pressure sensor 700 with the second plate 720 removed, according to an example embodiment. This shows that the piezoelectric columns, such as 732, 734, 736 are actually ring-shaped. The ring-shaped piezoelectric material portions have openings therein, 731, 733, 735, respectively. The openings 731, 733, 735 in the middle of the piezoelectric portions 732, 734, 736 can receive a fastener, such a screw or bolt. The fasteners (not shown) pass through the openings 731, 733, 735 and attach the first plate 710 to the second plate 720.

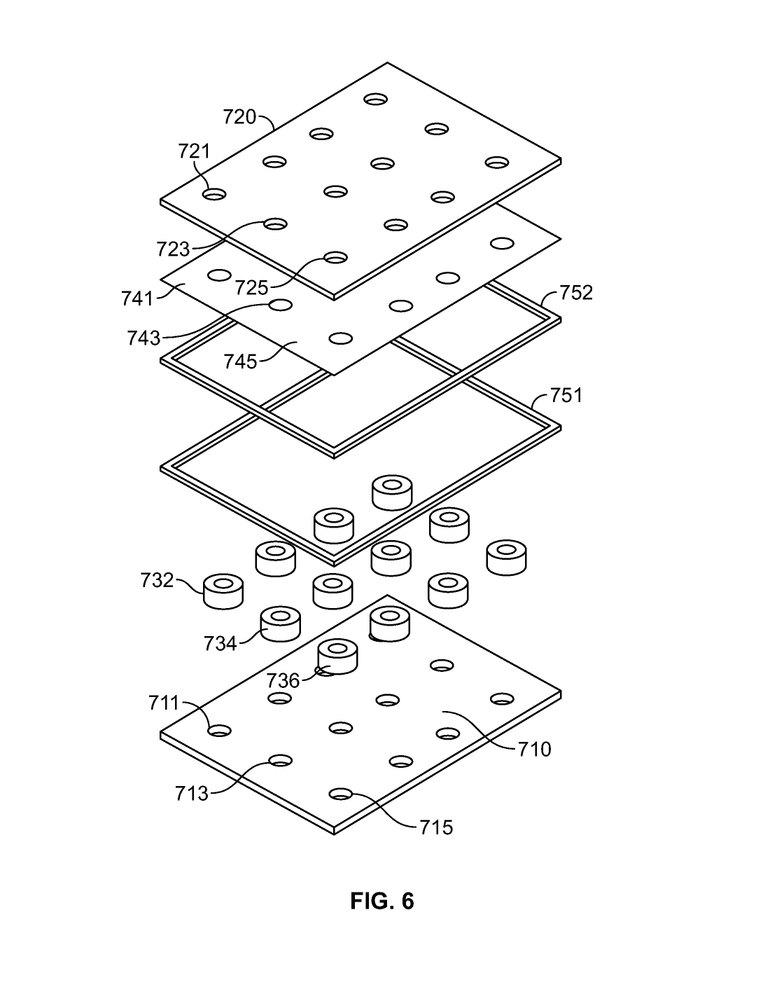

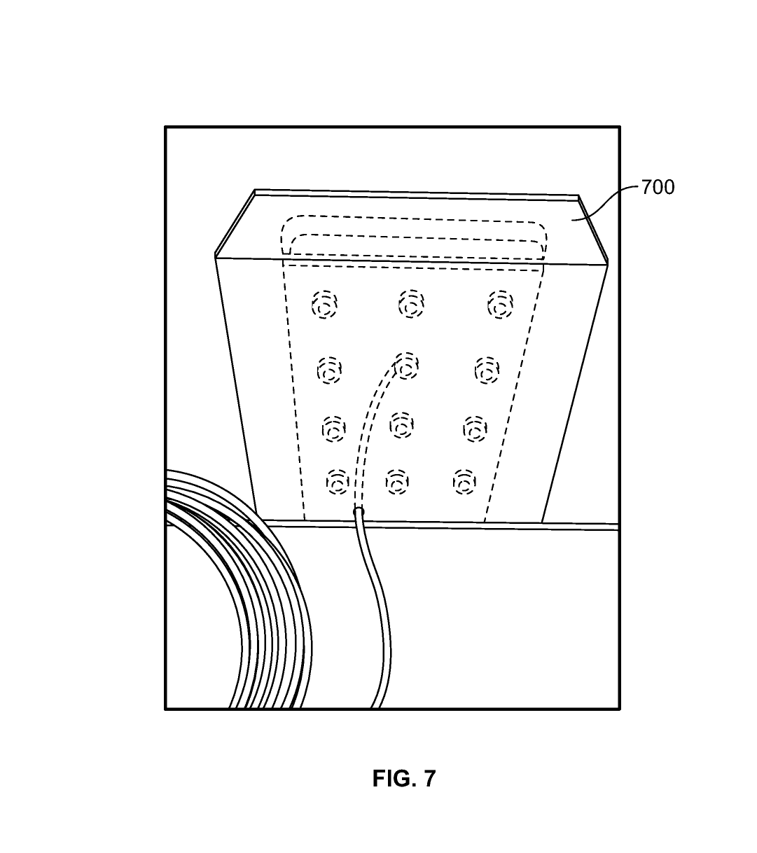

FIG. 6 is a blown up perspective view of an acoustic pressure sensor 700, according to an example embodiment. In this example embodiment, there are twelve piezoelectric portions, such as 732, 734, 736 that are ring-shaped. Each ring-shaped piezoelectric material portion 732, 734, 736 has an opening therein, such as openings 731, 733, 735, respectively. The first plate 710 and the second plate 720 also include twelve openings. As shown plate 710 includes openings 711, 713, 715 amongst the twelve openings, and plate 720 includes openings 721, 723, 725 amongst the twelve openings on that plate 720. The openings in the first plate 710 and the openings in the second plate 720 substantially align. In some embodiments of the pressure sensor 700, a spacer can be provided. The spacer also includes twelve openings, such as openings 741, 743, and 745. The openings 741, 743, and 745 are sized to receive the ring-shaped piezoelectric material portions, such as 732, 734, 736 and hold them in proper alignment so that a fastener can pass through opening 725 in plate 720, opening 735 in ceramic piece 736, and opening 715 in plate 710. The sensor 700 includes an acoustic isolation wall around perimeter of the sensor plates 710, 720. The wall can be a single part or a an assembly that includes several parts. As shown in FIG. 6, the wall 750 includes a first wall component 751 and a second wall component 752 that form the acoustic wall 750. This wall must be sufficiently stiff to resist movement from the acoustic waves but decoupled from the first plate 710 and the second plate 720 (caps) with a flexible layer to prevent the two caps from being bonded together. In one embodiment, the wall can be molded directly into the cap to reduce part count. A shorter wall could be molded into both the first plate 710 and second plate 720 (caps). In this embodiment, when the two plates are caps are assembled a wall will formed. A flexible layer will be required in each of these configurations to prevent the two caps or plates from effectively bonding together.

Fasteners, such as screws or bolts placed through the ceramic centers and the plates 710, 720 support alignment, coupling, and “bond” strength of the assembled sensor 700. Once assembled, the sensor is placed in a mold and urethane plastic or some other waterproof material having the same or similar properties as water (seawater or fresh water) is pumped into the chamber, pressurized and held at temperature for an amount of time. The urethane or other material must not fill the interstitial spaces your between the components making up the sensor 700 to leave an essential air gap allowing for coupling of the incident acoustic wave with the piezoelectric material. In one example embodiment a flexible material spacer could fill the space between the piezoelectric pieces to prevent a material such as urethane or water from filling the space. In one example embodiment, a layer of electrically isolative material is inserted between the ceramic and one of the first plate 710 or the second plate 720. In this example embodiment, the plate/wall housing can be used to achieve full electrical shielding for the sensor 700. Of course, it is contemplated that in alternative embodiments, the shape and size of these sensors as well as the quantity of ceramics in each sensor assembly could be varied. The sensors discussed above deliver increased sensitivity above baseline through a unique low cost geometry of piezoelectric material to plate coupling.

FIG. 7 is a perspective view of a finished acoustic pressure sensor 700, according to an example embodiment. The sensor 700 is encased in urethane material 1000. The resulting sensor 700 has a low-profile; and works in current reflecting plate scenarios. The example embodiment has no tabs to break so it is more rugged than some current designs. In addition, the sensor 700 is lightweight when compared to sensors having a solid ceramic plate and has a weight of approximately 7.5 g/cm². In addition, noise figure of merit is 10 dB higher than sensors that have a lead titanate design. In another embodiment, the ceramic thickness of the piezoelectric portions is doubled, and the noise figure of merit increases 40%. The sensor 700 also substantially maximizes flow noise area averaging.

The sensors 600, 700 or hydrophones are designed to work in frequency ranges where the wavelength is greater than the size of the transducer. This region results in a mostly omnidirectional transducer where the entire sensor is engulfed in each pressure wave. It should be noted, that other sensors that are less than ⅛ of the wavelength in thickness can benefit from reflection gain from a signal conditioning plate when in an array. The polarization direction in the embodiment of sensors 600, 700 is axial. In other words, the hydrophone or sensor 600, 700 ceramic is active in the 3-3 mode. When active in the 3-3 mode, the voltage is measured from electrodes in the same direction as the ceramic is polarized. The above described structure will work on other types of sensors. For example, the same geometry could also be expanded to use materials in the 3-1 mode where the polarization direction is orthogonal to the voltage electrode direction for materials that make this mode desirable.

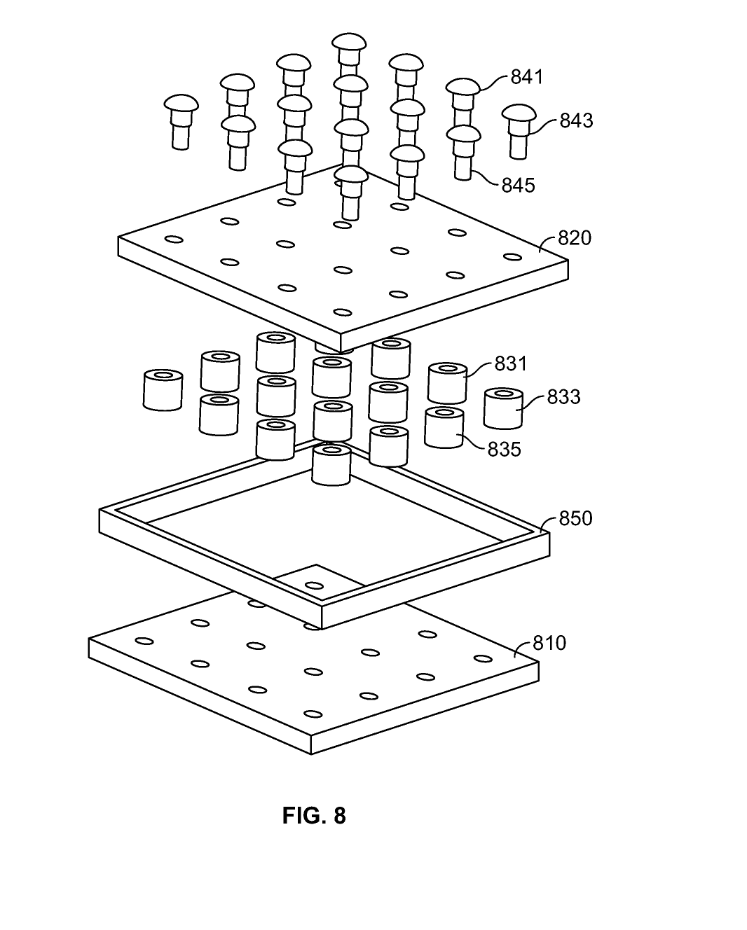

FIG. 8 is a blown up perspective view of another embodiment of an acoustic pressure sensor 800, according to an example embodiment. The pressure sensor 800 and includes a first plate 810 and a second plate 820. The pressure sensor 800 is substantially square in shape and includes 16 piezoelectric portions, such as 831, 833, 835. Each of the PAs electric portions 831, 833, 835 includes an opening therein which is sized to receive a fastener, such as fasteners 841, 843, 845. The first plate 810 also includes openings which correspond to the fasteners 841, 843, 845. Similarly the second plate also includes openings which correspond to the fasteners 841, 843, 845. Also included in the pressure sensor 800 is a wall 850. The wall 850 is a unitary unit which provides acoustic isolation at the perimeter of the sensor plates 810, 820. The wall 850 can be thought of as a frame sized to substantially match the perimeter of the sensor plates 810, 820. The frame or wall 850 is sufficiently stiff to resist movement from the acoustic waves while being decoupled from the first plate 810 and the second plate 820. The decoupling prevents the wall from joining or bonding the first plate 810 and the second plate 820 and maintains the acoustic isolation of the elements within the frame or wall 850.

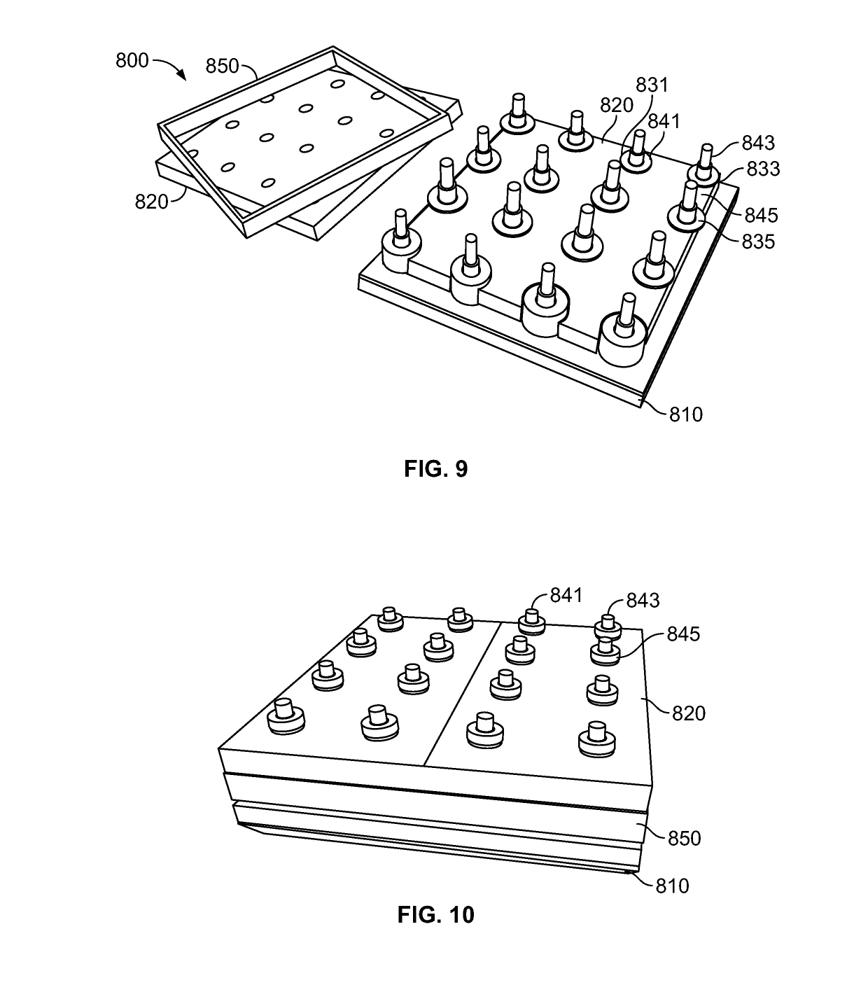

FIG. 9 is a perspective view of a square acoustic pressure sensor partially assembled, according to an example embodiment. As shown, the fasteners 841, 843, 845 have passed through the first plate 810 and through the openings in the ring shaped piezoelectric portions 831, 833, 835. To complete the assembly, the frame or wall 850 has to be placed about the perimeter of the first and second plates 810, 820. As a practical matter, the frame 850 will be placed onto the outer perimeter of the first plate 810 as shown in FIG. 9. The second plate 820 will then be placed onto the fasteners, such as fasteners 841, 843, 845 to complete the assembly. It should be noted that is shown in FIG. 9, acoustically isolated material is placed between the piezoelectric portions during assembly so that it is captured between the first plate 810 the second plate 820 and the wall 850. FIG. 10 is a perspective view of a square acoustic pressure sensor as assembled, according to an example embodiment. In other words FIG. 10 is a perspective view of the square acoustic pressure sensor 800 after the partial assembly of FIG. 9 is completed. It should be noted that the first plate 810 second plate 820 are made of aluminum. In other embodiments of the invention the first plate and second plate are made of steel. The assembly shown in FIG. 10 generally encased in urethane or a similar material so the sensor is sufficiently ruggedized to work in various environments, such as in an ocean or other environment.

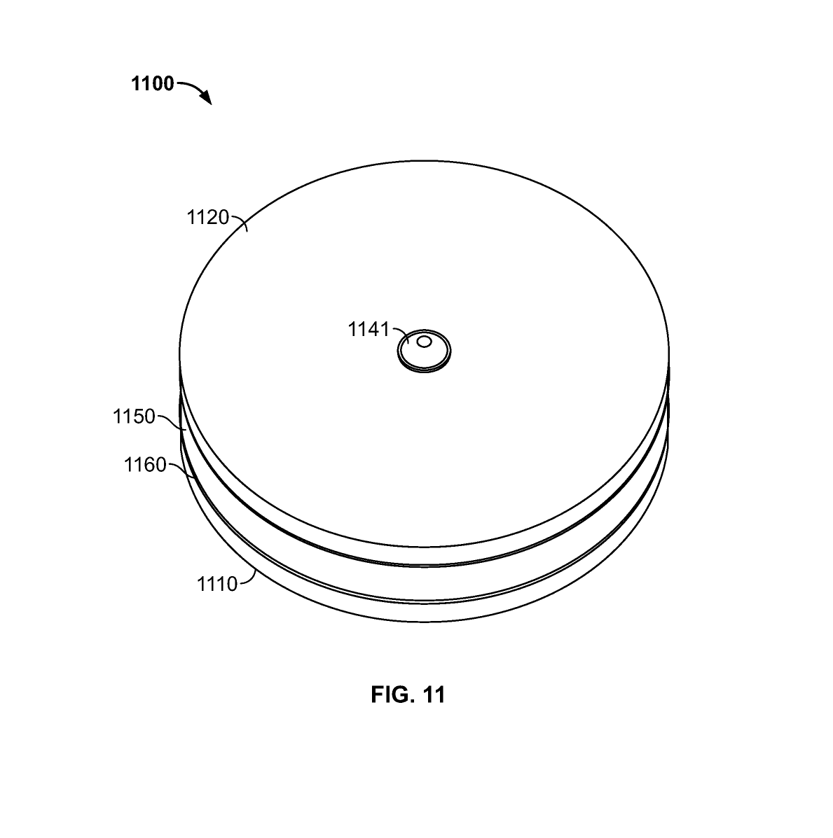

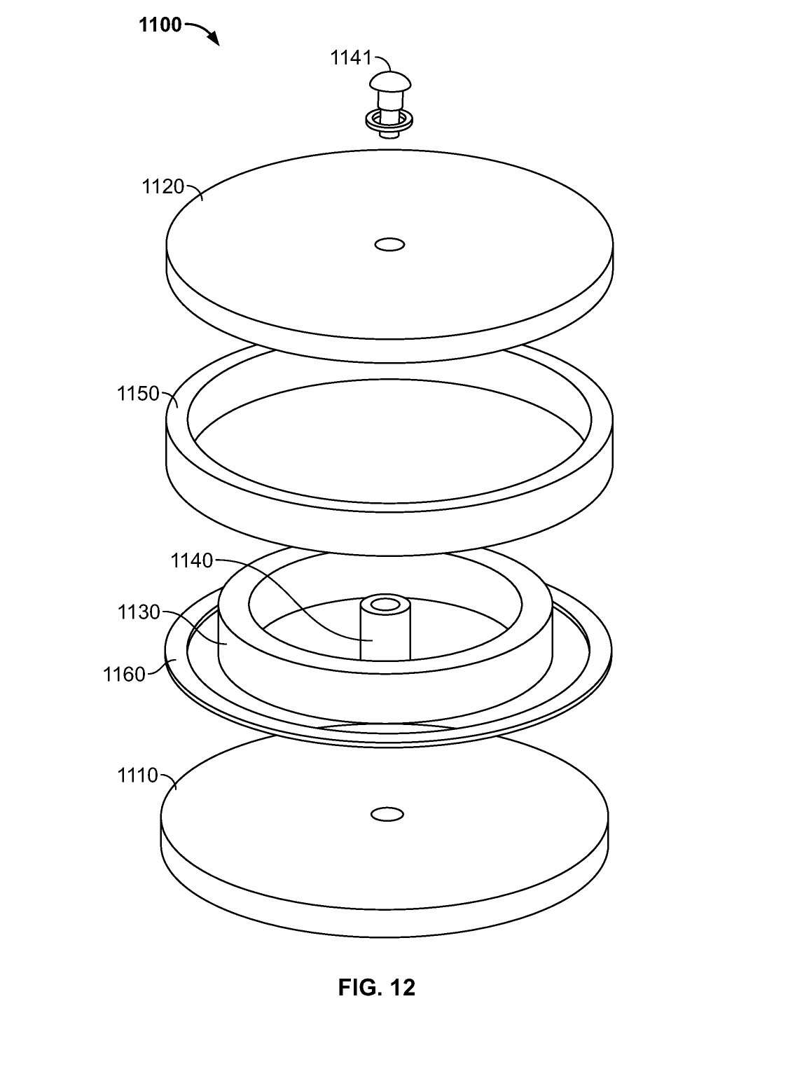

FIG. 11 is a perspective view of a round acoustic pressure sensor 1100 as assembled, according to an example embodiment. FIG. 12 is a blown up perspective view of a round acoustic pressure sensor 1100, according to an example embodiment. Now referring to both FIGS. 11 and 12, the round acoustic pressure sensor 1100 will be further detailed. As shown, the round sensor 1100 includes a first round plate 1110 and a second round plate 1120 and a wall 1150. The wall 1150 is annular. The wall has an outside perimeter which is substantially the same as the outside perimeter of the first plate 1110 and the second plate 1120. The sensor 1100 also includes a piezoelectric ring 1130. The round sensor 1100 can also include a center support structure 1140 to stiffen the caps (first plate 1110 and second plate 1120). If the caps (first plate 1110 and second plate 1120) are too flexible, they will not effectively transfer the acoustic pressure into the piezoelectricity. The support structure 1140 is generally not made of a piezoelectric material and is made of a material that will support the first plate 1110 and the second plate 1120. As shown in FIG. 12, the support structure 1140 is centered with respect to the first plate 1110 and the second plate 1120. The support structure 1140 also is tubular in shape and has an opening which can receive a fastener 1141. The fastener 1141 passes through the first plate 1110 the support structure 1140 and the second plate 1120. As mentioned above, the support structure provide stiffness to the first plate 1110 and the second plate 1120 which is spanning the space between the wall 1150 and the piezoelectric element 1130. The area ratio between the center support 1140 and the piezo-electric material 1130 should be at least 1:10 so that the center support 1140 does not interfere with transferring load through the piezo-electric material 1130. In one embodiment the center support structure 1140 is a separate element. In another embodiment, the center support may be molded directly into the caps (the first plate 1110 and the second plate 1120) to reduce part count. Also included in the sensor 1100 is a flexible layer 1160 which prevents the wall 1150 from coupling or bonding together the first plate 1110 and the second plate 1120.

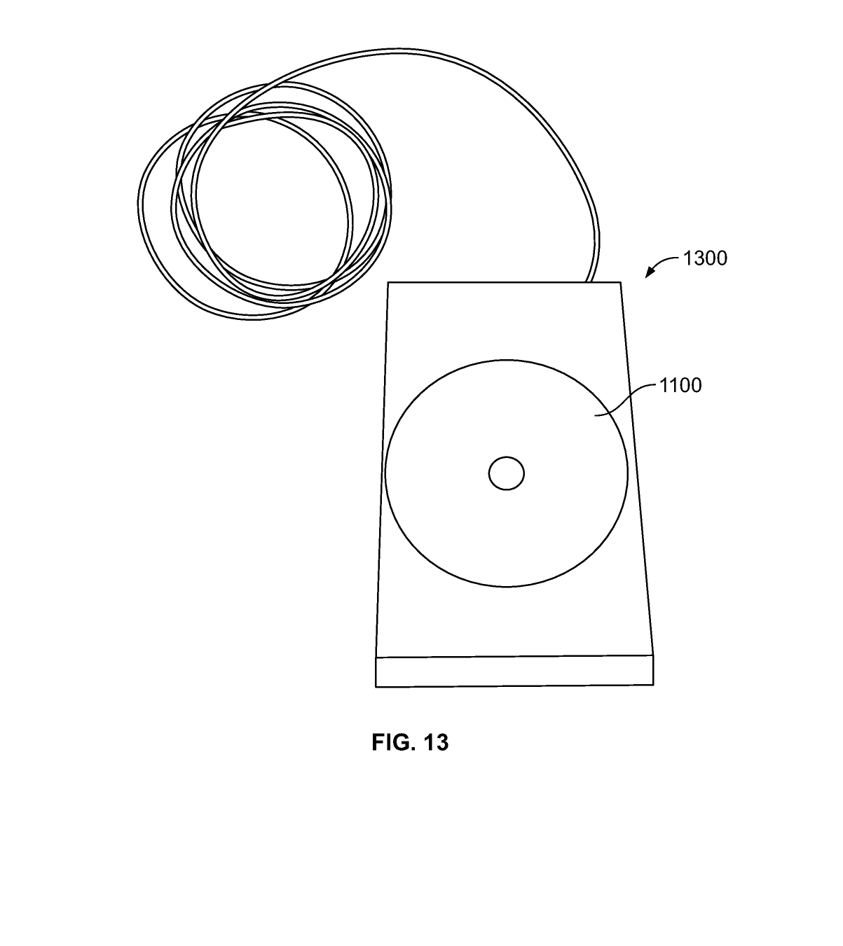

FIG. 13 is a perspective view of the round acoustic pressure sensor 1100 encased in a urethane material, according to an example embodiment. The urethane material ruggedized as the archer sensor 1100 so they can be used in various environments. The urethane material generally will not affect the ability of the sensor 1100 to detect pressure waves. The final assembly also includes electrically coupling the PAs electric element 1130 (shown in FIG. 12). As shown in FIG. 13, wires attached to the ring provide the electrical coupling.

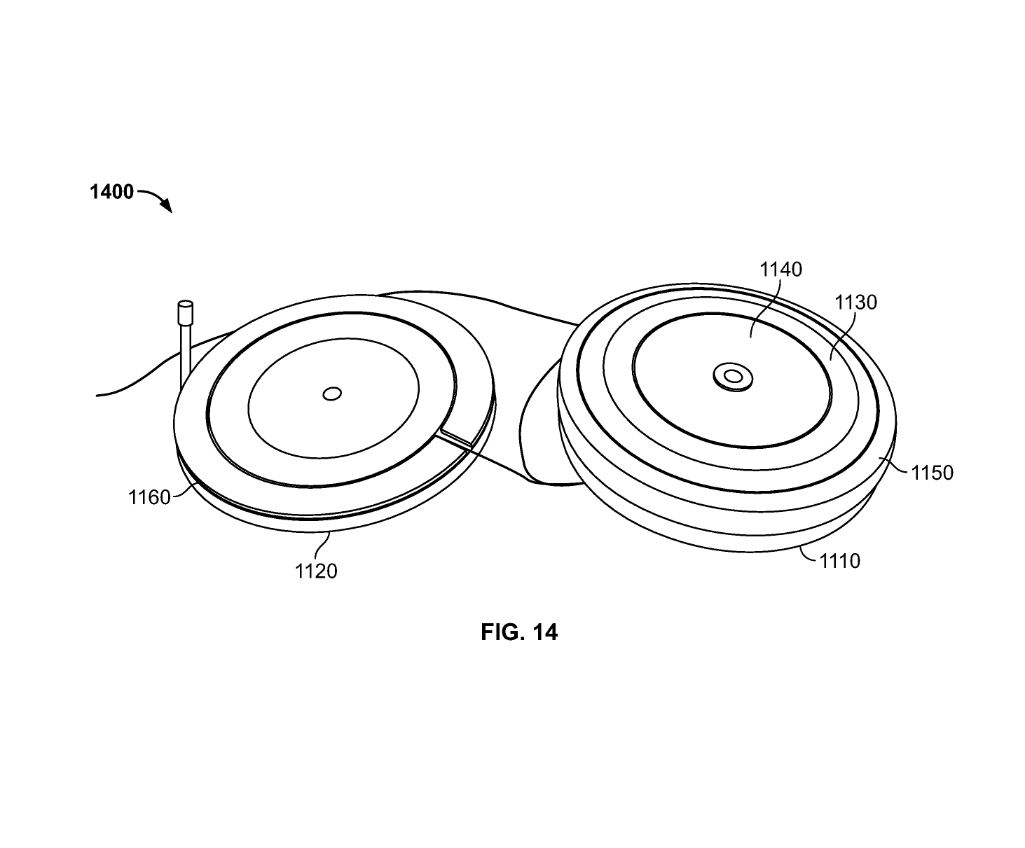

FIG. 14 is a perspective view of a partially assembled round acoustic pressure sensor 1400, according to an example embodiment. The acoustic pressure sensor 1400 is very similar to the acoustic pressure sensor 1100. Rather than describe the pressure sensor 1400 in detail, for the sake of clarity and brevity, only the differences between the pressure sensor 1100 and the pressure sensor 1400 will be discussed. As shown in FIG. 14 the piezoelectric element 1130 is encased in acoustically isolated material. In the pressure sensor 1100, acoustically isolated material can also be placed about the piezoelectric element 1130. Among the differences is that the ring 1160 of the coupling material between the first plate 1110 and the second plate 1120 is placed directly onto the second plate 1120. This reduces the part count and eases assembly of the sensor 1400.

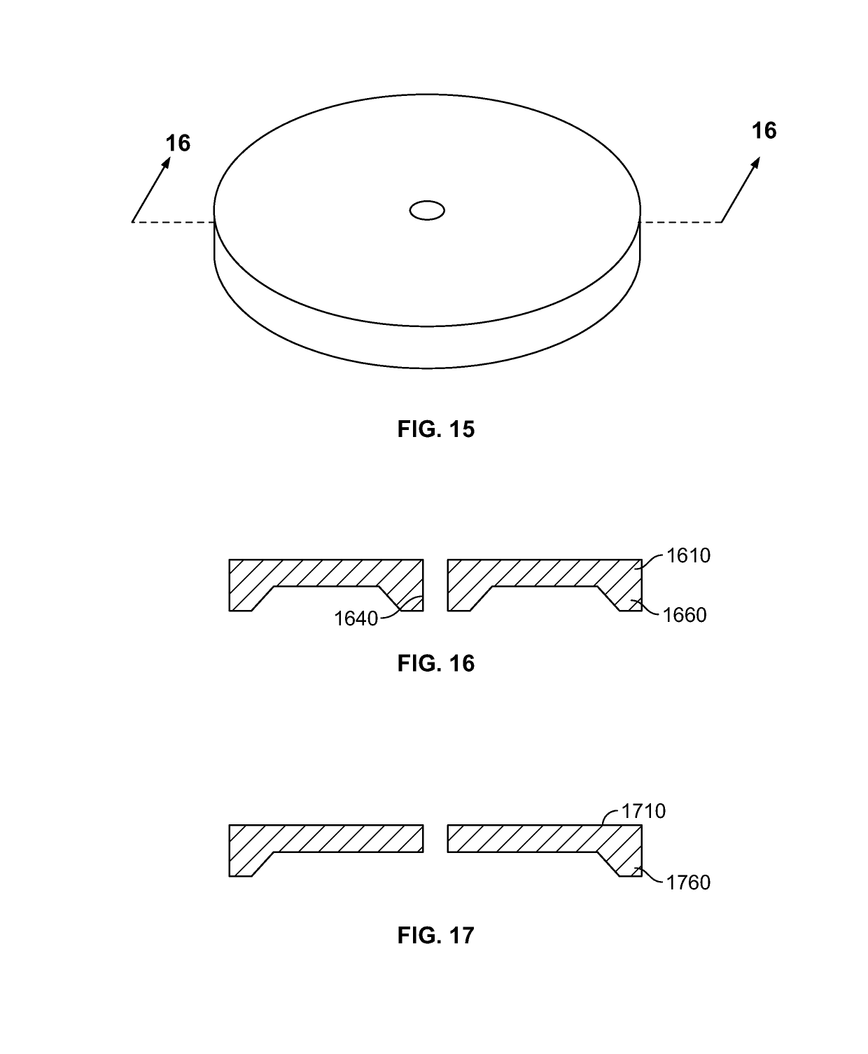

FIG. 15 is a perspective view of a fully assembled round acoustic pressure sensor 1500, according to an example embodiment. Sensors 1500 could be assembled in a number of different ways. The basic idea of sensor 1500 is that the wall 1150 of the previous sensors 1100, 1400 can be incorporated into the first plate and the second plate. Now referring to both FIGS. 16 and 17, two possible cross-sectional areas of the first plate and the second plate will now be shown.

FIG. 16 is one possible cross-section view along line A-A in FIG. 15, according to an example embodiment. The first plate 1610 includes a wall 1660 and a support structure 1640. The wall 1660, in one embodiment, is a half wall. In other words the second plate will be similarly shaped in dimensioned so that when the first plate 1610 and the second plate are connected they form the wall 1660. Similarly the support structure 1640 is also a half wall or half support so that the first plate 1610 and second plate are similarly shaped. It should be understood that the wall 1660 of the first plate 1610 could also be a full wall and that the support structure 1640 can also be a full support structure. In this case, a flat second plate would be connected to the first plate 1610 to form the round sensor 1500.

FIG. 17 is one possible cross-section view along line A-A in FIG. 15, according to an example embodiment. In this particular embodiment, the first plate 1710 is provided with a wall 1760. Unlike the first plate 1610, the first plate 1710 does not include a support structure. The wall 1760 could be a half wall or a full wall. A separate support structure, such as support structure 1140 (shown in FIG. 12) could be used. Of course, during assembly the first plate and second plate must be separated by a dampening material so as not to bond or unify the first plate and the second plate.

This has been a detailed description of some exemplary embodiments of the invention(s) contained within the disclosed subject matter. Such invention(s) may be referred to, individually and/or collectively, herein by the term “invention” merely for convenience and without intending to limit the scope of this application to any single invention or inventive concept if more than one is in fact disclosed. The detailed description refers to the accompanying drawings that form a part hereof and which shows by way of illustration, but not of limitation, some specific embodiments of the invention, including a preferred embodiment. These embodiments are described in sufficient detail to enable those of ordinary skill in the art to understand and implement the inventive subject matter. Other embodiments may be utilized and changes may be made without departing from the scope of the inventive subject matter. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

What is claimed:

1. A sensor comprising:
a first plate;
a second plate; and
a plurality of piezoelectric material portions positioned between the first plate and the second plate.

2. The sensor of claim 1 wherein the plurality of piezoelectric material portions have a cross sectional area which is less than the cross sectional area of the first plate or the second plate.

3. The sensor of claim 1 wherein the plurality of piezoelectric material portions have a cross sectional area and the first plate and the second plate have a cross sectional area, the ratio of the cross sectional area of the piezoelectric portions to the cross sectional area of one of the first plate and the second plate being in the range of 1:3 to 1:11.

4. The sensor of claim 1 wherein the plurality of piezoelectric material portions are ceramic.

5. The sensor of claim 1 wherein the plurality of piezoelectric material portions are ceramic posts.

6. The sensor of claim 1 wherein the plurality of piezoelectric material portions include openings therein for receiving a fastener, the fastener attaching at least one of the piezoelectric material portion and the first plate and the second plate.

76. The sensor of claim 6 wherein the fastener aligns at least one of the piezoelectric material portion and the first plate and the second plate.

8. The sensor of claim 1 further comprising a layer of electrical isolation material placed between the portion of piezoelectric material and at least one of the first plate and the second plate.

9. The sensor of claim 7 wherein at least one of the first plate and the second plate are used to electrically shield the sensor.

10. The sensor of claim 1 further comprising an acoustic isolation material positioned around the piezoelectric portions of the sensor.

11. The sensor of claim 10 wherein the acoustic isolation material is positioned near the perimeter of the sensor, the acoustic isolation material including:
a stiff portion that surrounds the piezoelectric portions; and
a small flexible layer between the first plate and the second plate.

12. The sensor of claim 10 wherein the acoustic isolation material is formed into at least one of the first plate or the second plate.

13. The sensor of claim 1 further comprising a support member located within a piezoelectric portion and between a first plate and a second plate.

14. The sensor of claim 13 wherein the support member is integral with at least one of the first plate and the second plate.

15. The sensor of claim 1 wherein at least one of the first plate and the second plate are made of a composite material.

16. The sensor of claim 1 having a substantially polygon shape.

17. The sensor of claim 1 having a thickness less than ⅛ of the wavelength of the sound wave received.

18. The sensor of claim 1 wherein the space between the plurality of piezoelectric material and the first plate and the second plate is filled with an acoustic isolation material.

19. A method of forming a sensor comprising:
selecting a first plate and a second plate of a first material;
selecting a size, shape, and number of piezoelectric portions to accommodate system weight, performance, and cost requirements;
placing the piezoelectric portions on one of the first plate or the second plate;
fastening the first plate to the second plate to one another by passing a fastener through at least one of the piezoelectric portions.

20. The method of clam 19 further comprising:
placing an acoustically isolating material around at least one piezoelectric portion; and
preventing bonding between the first plate and the second plate.
